(19) United States
(12) Patent Application Publication
(10) Pub. No.: US 2026/0026025 A1
(43) Pub. Date: Jan. 22, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Ching-Sheng CHU, Hsinchu (TW); Chi-Ming CHEN, Zhubei City (TW); Eugene I-Chun CHEN, Zhubei City (TW); Chia-Shiung TSAI, Hsinchu City (TW)

(21) Appl. No.: 18/774,366

(22) Filed: Jul. 16, 2024

(51) Int. Cl. H01L 29/66; H01L 21/02; H01L 23/528; H01L 29/20; H01L 29/778

(52) U.S. Cl. CPC H10D 30/015; H01L 21/02458; H01L 21/0254; H01L 23/5283; H10D 30/475; H10D 62/8503

(57) ABSTRACT

Scribe line channels are formed between semiconductor dies that are formed on a gallium nitride (GaN) layer using an aluminum nitride-based (AlN-based) core substrate. The scribe line channels are formed to expose a release layer under the GaN layer, which enables the release layer to be etched through the scribe line channels to remove the semiconductor dies from the AlN-based core substrate with minimal to no damage to the AlN-based core substrate. In this way, the scribe line channels enable the AlN-based core substrate to be reused for subsequent GaN layer growth, and increase the number of times that the AlN-based core substrate can be reused to form GaN-based semiconductor devices. This reduces the cost and complexity of manufacturing GaN-based semiconductor devices.

### BACKGROUND

Gallium nitride (GaN)-based materials offer several advantageous electrical properties, mechanical properties, and chemical properties over other types of semiconductor materials, such as a wide band gap, a high breakdown voltage, a high electron mobility, a large elastic modulus, high piezoelectric and piezoresistive coefficients, and chemical inertness. Such advantages make GaN-based materials attractive for making semiconductor devices such as power management devices, high brightness light-emitting diodes (LEDs), and other types of semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1F are diagrams of an example implementation of forming a gallium nitride (GaN) layer on a core substrate described herein.

FIGS. 2A-2N are diagrams of an example implementation of forming GaN-based semiconductor devices on a GaN layer that was formed on a core substrate described herein.

FIG. 3 is a diagram of an example implementation of a GaN-based semiconductor device described herein.

FIG. 4 is a flowchart of an example process associated with forming a GaN-based semiconductor device described herein.

FIG. 5 is a flowchart of an example process associated with forming a GaN-based semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Gallium nitride-based (GaN-based) high-electron-mobility transistors (HEMTs) are HEMTs that are formed on a GaN layer. GaN-based HEMTs may offer high operating voltages (e.g., 650 volts to 1200 volts or greater) and high-frequency switching speeds for radar, power switching, and millimeter wave communications, among other examples. A GaN-based HEMT may be formed on a GaN layer that is grown on a core substrate that includes an aluminum nitride (AlN) core. A layer stack may be formed on and/or bonded to the aluminum nitride core, and the GaN layer may be grown on the layer stack by epitaxial growth. The layer stack includes a combination of materials that has a combined coefficient of thermal expansion (CTE) similar to the CTE of the GaN layer to prevent, minimize, and/or otherwise reduce the likelihood and/or amount of cracking in the GaN layer due to thermal expansion and contraction.

AlN-based core substrates are often manufactured in low production volumes and using costly processes such as compression and sintering of AlN powder. Additionally, AlN-based core substrates are single-use, because after GaN-based HEMTs are formed on the GaN layer that is grown on an AlN core of a core substrate, the core substrate is destroyed by grinding and etching processes. The single-use nature of AlN-based core substrates increases the cost and complexity of manufacturing GaN-based HEMTs and other GaN-based semiconductor devices.

In some implementations described herein, scribe line channels are formed between semiconductor dies that are formed on a GaN layer using an AlN-based core substrate. The scribe line channels are formed to expose a release layer under the GaN layer, which enables the release layer to be etched through the scribe line channels to remove the semiconductor dies from the AlN-based core substrate with minimal to no damage to the AlN-based core substrate. In this way, the scribe line channels enable the AlN-based core substrate to be reused for subsequent GaN layer growth, and increase the number of times that the AlN-based core substrate can be reused to form GaN-based semiconductor devices. This reduces the cost and complexity of manufacturing GaN-based HEMTs and other GaN-based semiconductor devices.

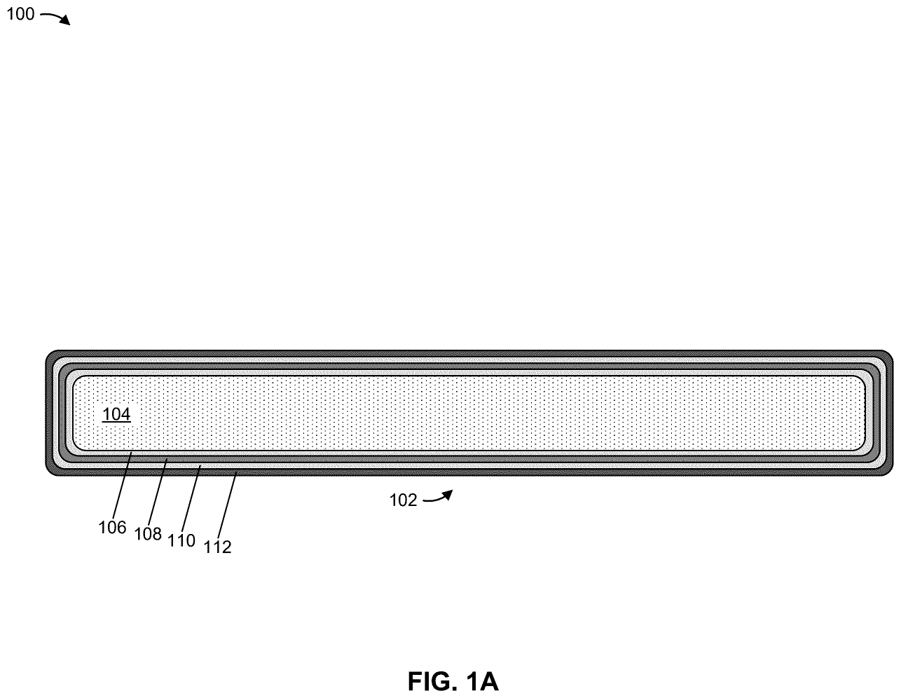

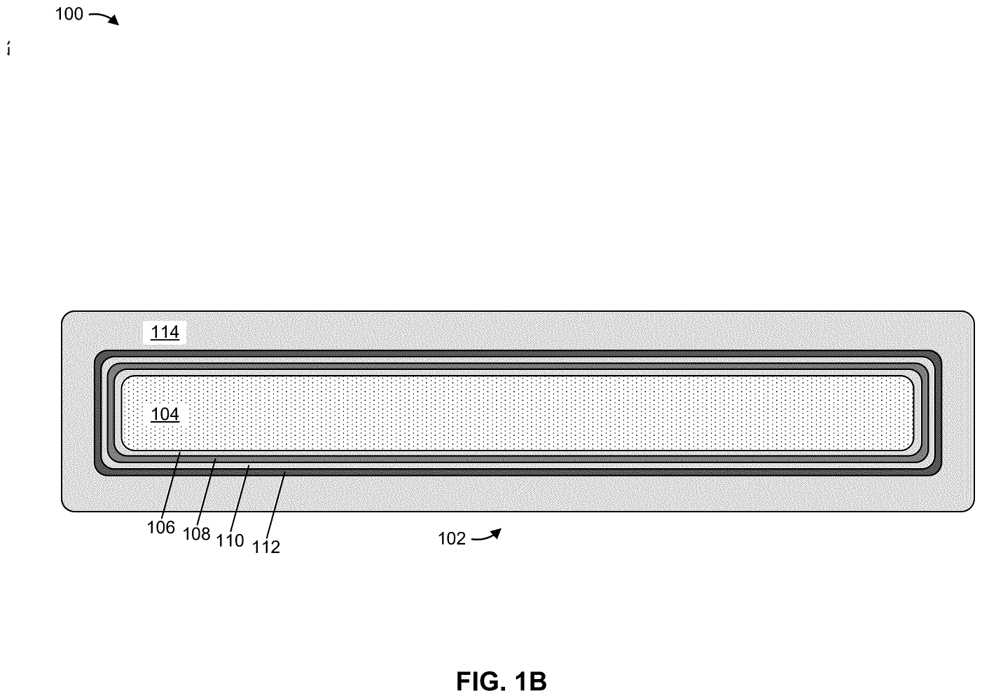

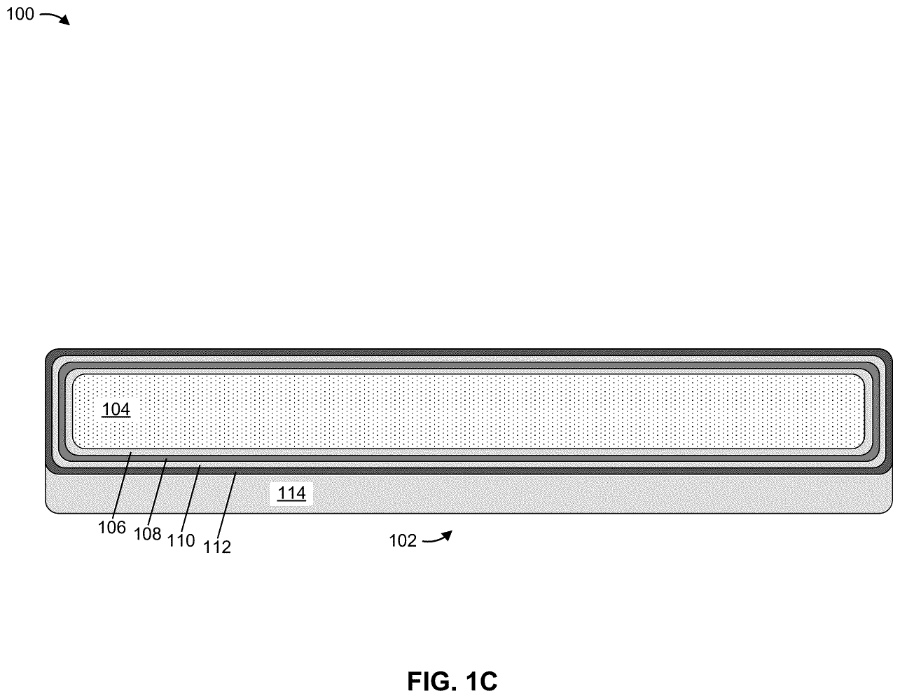

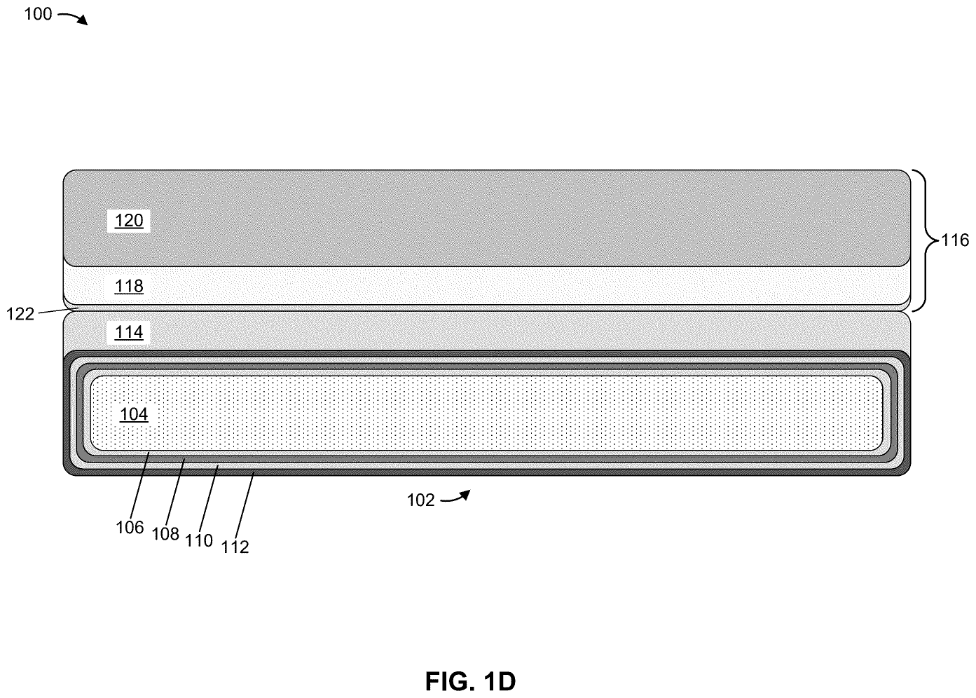

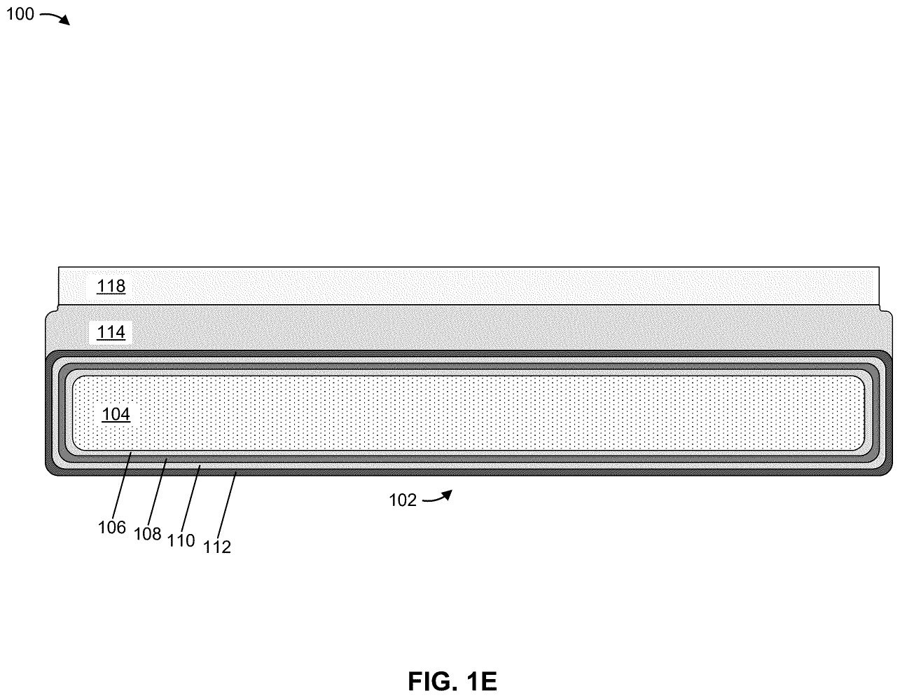

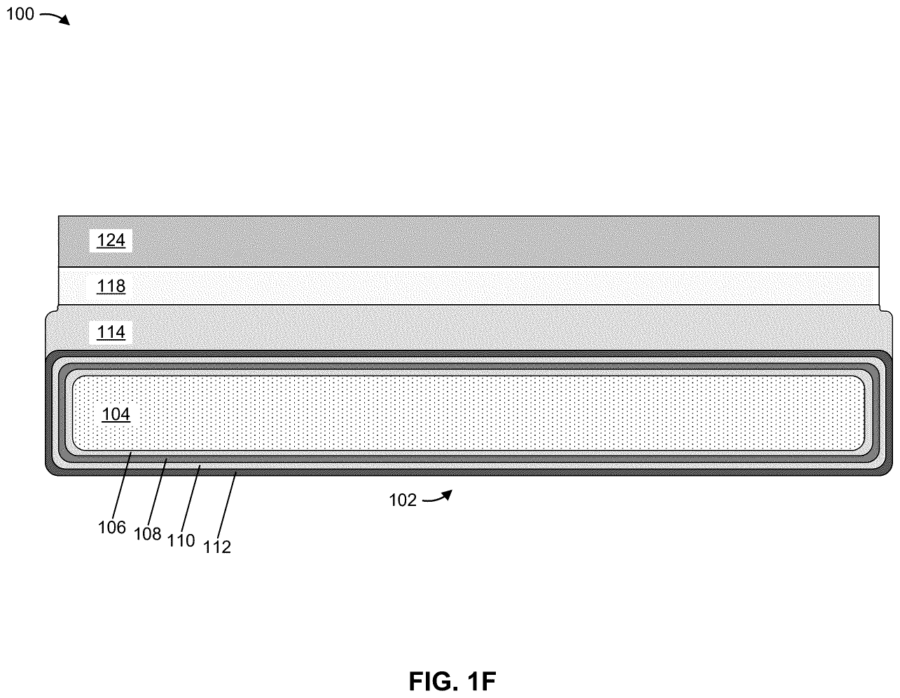

FIGS. 1A-IF are diagrams of an example implementation 100 of forming a GaN layer on a core substrate 102 described herein. The core substrate 102 includes a core substrate that can be used to grow a GaN layer on which GaN-based semiconductor dies may be formed.

As shown in FIG. 1A, the core substrate 102 includes an AlN core 104 and may therefore be referred to as an AlN-based core substrate. The AlN core 104 may be formed by compressing AlN powder (e.g., using a hydraulic compression tool or another type of press) and sintering (e.g., furnace sintering or another type of sintering process) the compressed AlN power to form the AlN core 104. In some implementations, the AlN powder is sintered at a temperature of approximately 2000 degrees Celsius or greater. In some implementations, another process may be performed to form the AlN core 104 of the core substrate 102. Alternatively, the core of the core substrate 102 may be formed of another material having a bandgap lattice constant that is included in a range of approximately 6 eV to approximately 6.5 cV.

As further shown in FIG. 1A, one or more layers may be formed on and/or around the AlN core 104 of the core substrate 102. For example, an adhesion layer 106 may be formed around the AlN core 104. As another example, a semiconductor layer 108 may be formed on the adhesion layer 106. As another example, another adhesion layer 110 may be formed on the semiconductor layer 108. As another example, a diffusion barrier layer 112 may be formed on the adhesion layer 110.

The adhesion layer 106 may include a silicon oxide (SiOₓ such as SiO₂) and/or another suitable material that promotes adhesion of the semiconductor layer 108 to the AlN core 104. The semiconductor layer 108 may be included to facilitate chucking of the core substrate 102 to one or more semiconductor processing tools for processing. In some implementations, the semiconductor layer 108 includes polysilicon and/or another suitable semiconductor material. The adhesion layer 110 may include a silicon oxide (SiOₓ such as SiO₂) and/or another suitable material that promotes adhesion between the semiconductor layer 108 and the diffusion barrier layer 112. The diffusion barrier layer 112 may include a silicon nitride (e.g., SiₓN_{y}) that inhibits the diffusion of materials between the AlN core 104 and layers that are subsequently formed on the core substrate 102.

A deposition tool may be used to deposit the adhesion layer 106, the semiconductor layer 108, the adhesion layer 110, and/or the diffusion barrier layer 112 using a physical vapor deposition (PVD) technique, an atomic layer deposition (ALD) technique, a chemical vapor deposition (CVD) technique, an oxidation technique, and/or another suitable deposition technique. In some implementations, the semiconductor layer 108 is formed to a thickness that is included in a range of approximately 400 angstroms (Å) to approximately 480 Å. However, other values for the range are within the scope of the present disclosure. In some implementations, the diffusion barrier layer 112 may be formed to a thickness that is included in a range of approximately 1800 Å to approximately 2200 Å. However, other values for the range are within the scope of the present disclosure.

As shown in FIGS. 1B and 1C, a bonding layer 114 is formed around the AlN core 104, and a portion of the bonding layer 114 may be subsequently removed from one of the surfaces of the core substrate 102 to facilitate chucking using the semiconductor layer 108. The bonding layer 114 may include a silicon oxide (SiOₓ such as SiO₂) and/or another suitable material that is used to bond a layer stack to the core substrate 102 by dielectric-to-dielectric bonding.

A deposition tool may be used to deposit the bonding layer 114 using a PVD technique, an ALD technique, a CVD technique, an oxidation technique, and/or another suitable deposition technique. The bonding layer 114 may be deposited in one or more deposition operations. In some implementations, a planarization tool may be used to perform a planarization operation (e.g., a chemical-mechanical planarization (CMP) operation) to planarize the bonding layer 114 after the bonding layer 114 is deposited. In some implementations, the bonding layer 114 may be formed to a thickness that is included in a range of approximately 2.7 microns (μm) to approximately 3.3 μm. However, other values for the range are within the scope of the present disclosure.

In some implementations, an etch tool is used to perform an etch operation to etch the bonding layer 114 to remove the bonding layer 114 from one of the surfaces of the core substrate 102. In some implementations, the etch operation includes a dry etch operation (e.g., a plasma-based etch operation, a gas-based etch operation), a wet chemical etch operation, and/or another type of etch operation. In some implementations, a planarization tool may be used to perform a planarization operation (e.g., a CMP operation) or a wafer grinding operation to remove the bonding layer 114 from one of the surfaces of the core substrate 102.

As shown in FIG. 1D, a layer stack 116 may be bonded to the core substrate 102. The layer stack 116 may include a semiconductor layer 118 that was epitaxially grown on a semiconductor substrate 120. A bonding tool may be used to perform a bonding operation to bond the bonding layer 114 on the core substrate 102 with a bonding layer 122 on the layer stack 116. The bonding layer 122 may include a similar material composition or a same material as the bonding layer 114. For example, the bonding layers 114 and 122 may each include silicon oxide (SiOₓ such as SiO₂) and/or another suitable material that enables a dielectric-to-dielectric bond to be formed between the bonding layers 114 and 122. The bonding operation may include a eutectic bonding operation and/or another type of bonding operation.

The semiconductor substrate 120 may include a silicon (Si) substrate and/or another type of substrate on which the semiconductor layer 118 may be epitaxially grown. In some implementations, the semiconductor layer 118 includes a layer of p (−) type of silicon (Si) material having a <111> grain orientation. In some implementations, the semiconductor layer 118 includes a layer of p(+) type of silicon (Si) material having a <111> grain orientation. The <111> grain orientation of the semiconductor layer 118 may promote nucleation of a GaN layer that is to be epitaxially grown on the semiconductor layer 118. However, other grain orientations are within the scope of the present disclosure.

As shown in FIG. 1E, the semiconductor substrate 120 is subsequently removed from the core substrate 102 after the semiconductor layer 118 is bonded to the core substrate 102. In some implementations, an etch tool is used to perform an etch operation to etch the semiconductor substrate 120 to remove the semiconductor substrate 120 from the core substrate 102. In some implementations, the etch operation includes a dry etch operation (e.g., a plasma-based etch operation, a gas-based etch operation), a wet chemical etch operation, and/or another type of etch operation. In some implementations, a planarization tool may be used to perform a planarization operation (e.g., a CMP operation) or a wafer grinding operation to remove the semiconductor substrate 120 from the core substrate 102.

As shown in FIG. 1F, a GaN layer 124 is formed on the semiconductor layer 118. The semiconductor layer 118 is used as a seed layer to epitaxially grow the GaN layer 124. A deposition tool may be used to deposit the material of the GaN layer 124 at a temperature that is included in a range of approximately 600 degrees Celsius to approximately 1000 degrees Celsius to promote nucleation of the GaN layer 124 and to promote growth of the GaN layer 124 in a crystal lattice structure. However, other values for the range are within the scope of the present disclosure. In some implementations, the GaN layer 124 is formed to a thickness that is included in a range of approximately 5 μm to approximately 10 μm. However, other values for the range are within the scope of the present disclosure.

As indicated above, FIGS. 1A-IF are provided as an example. Other examples may differ from what is described with regard to FIGS. 1A-IF.

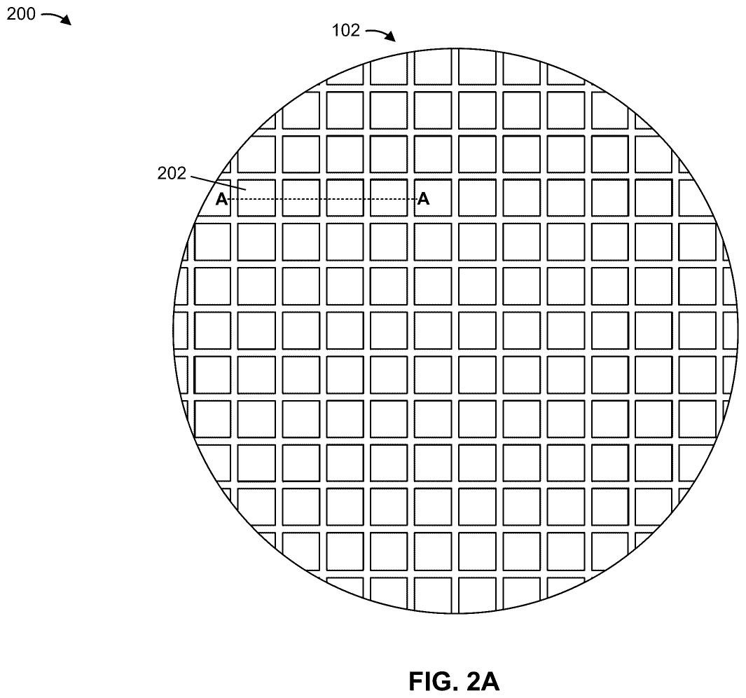

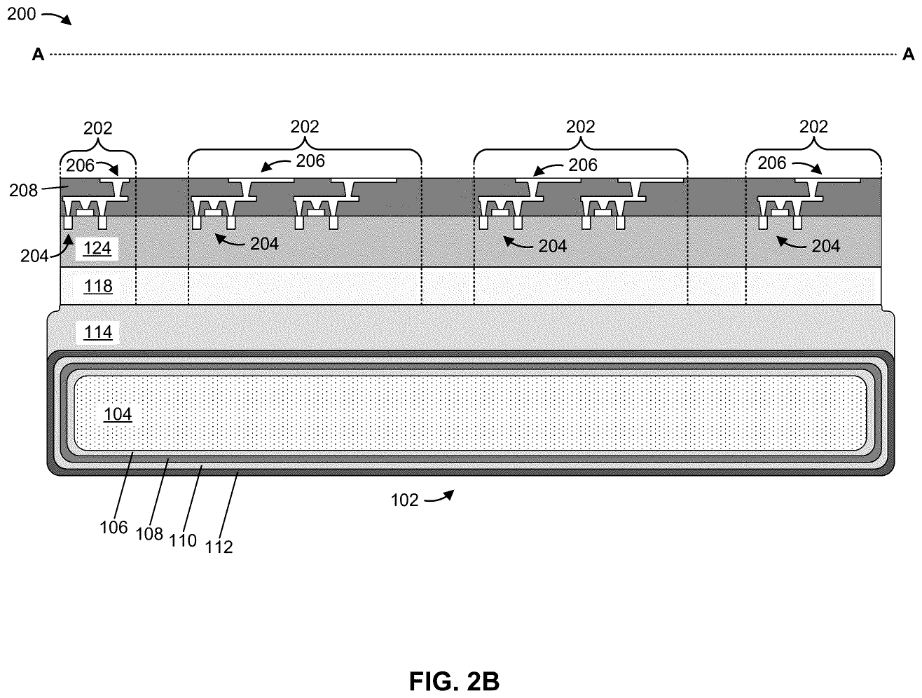

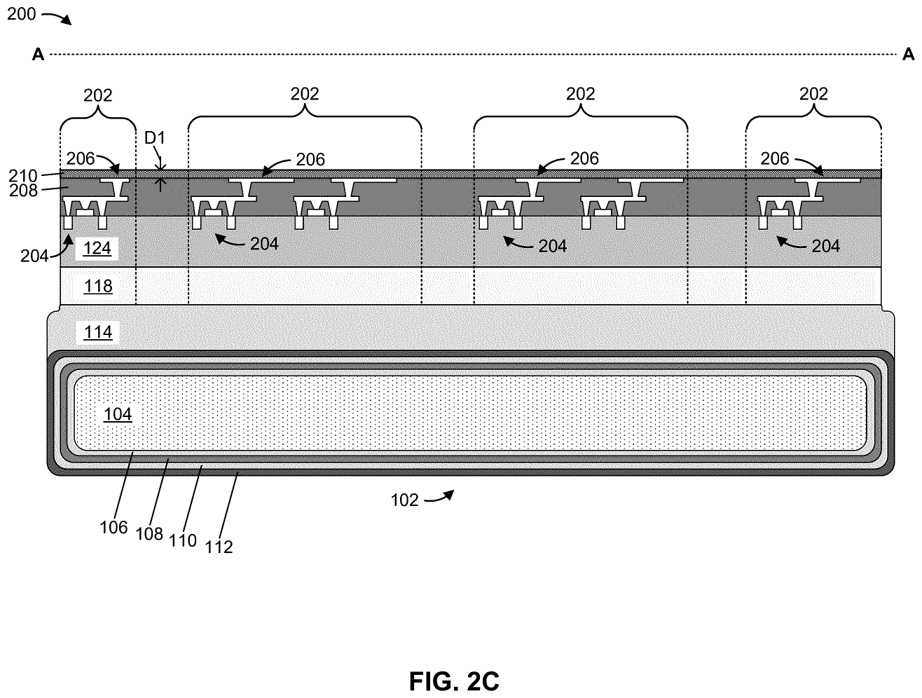

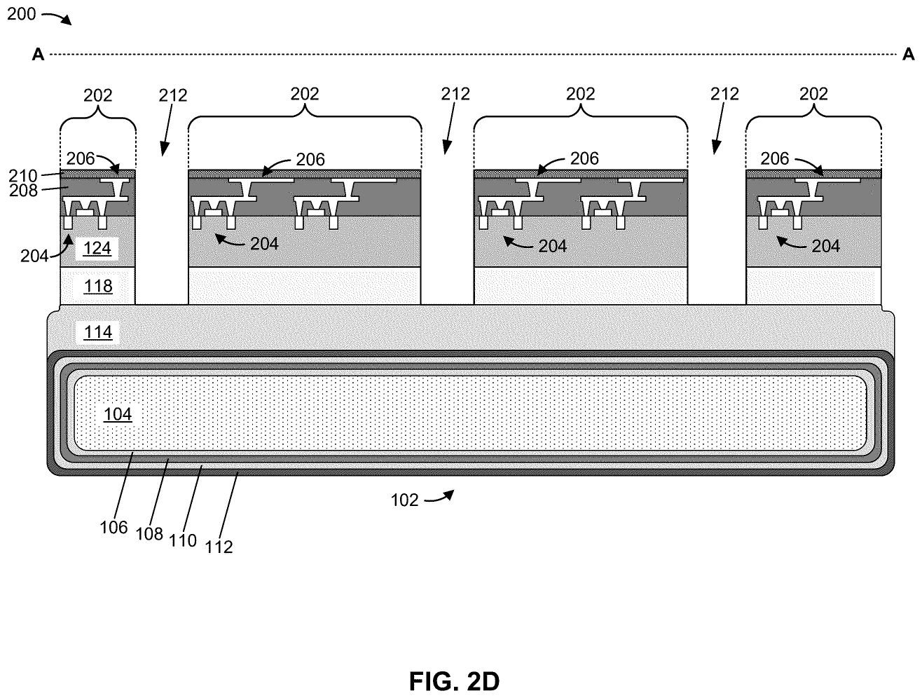

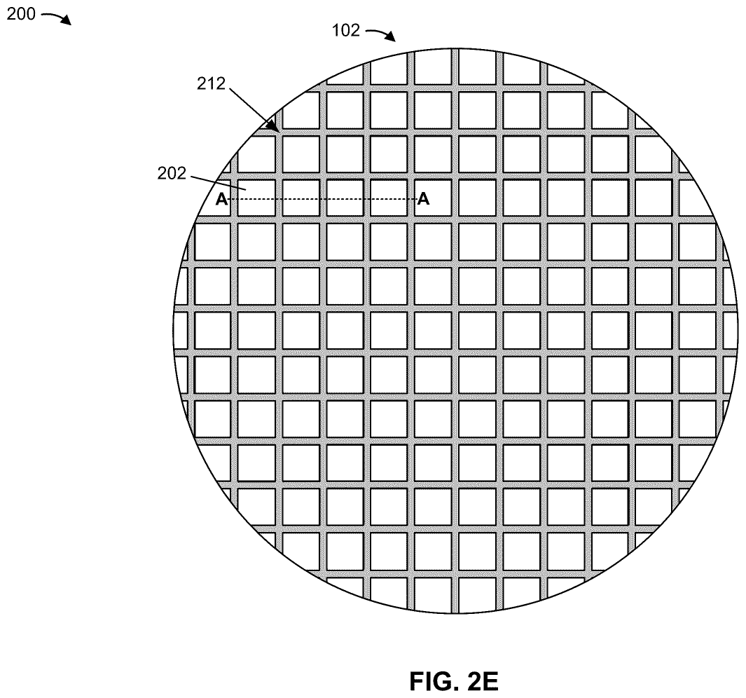

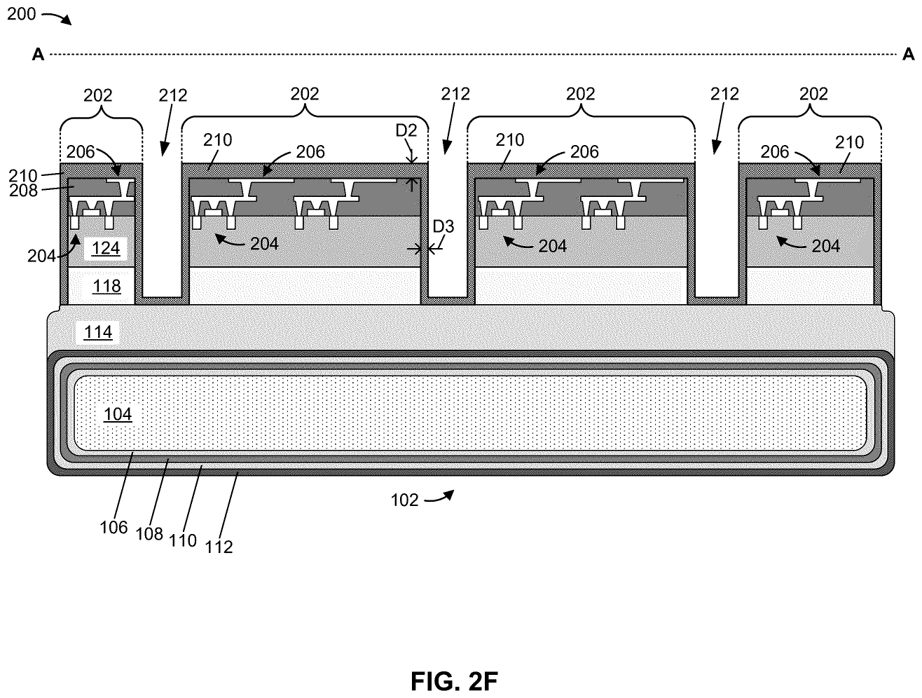

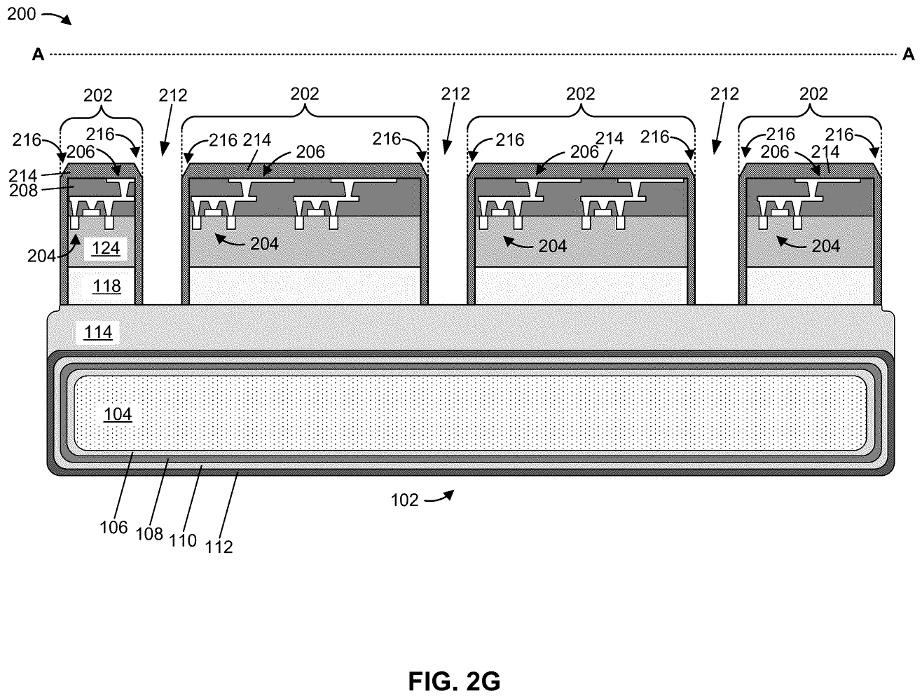

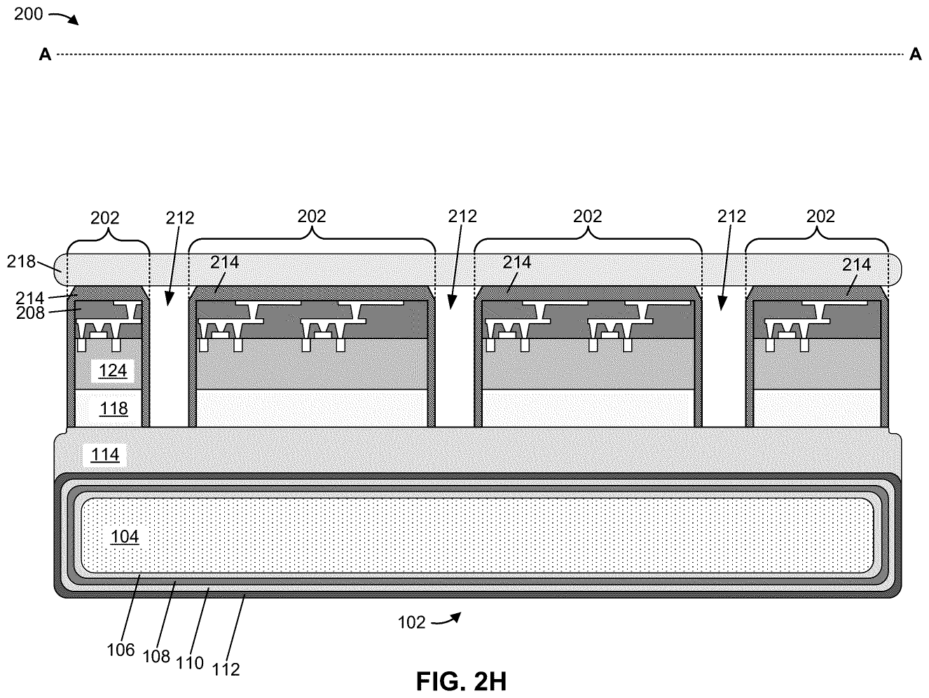

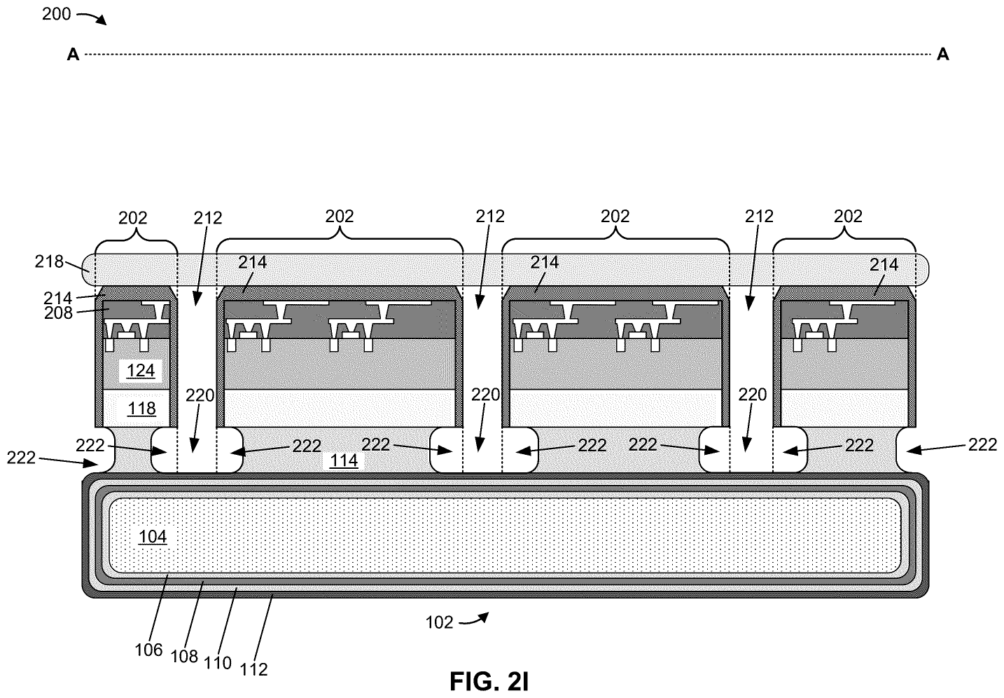

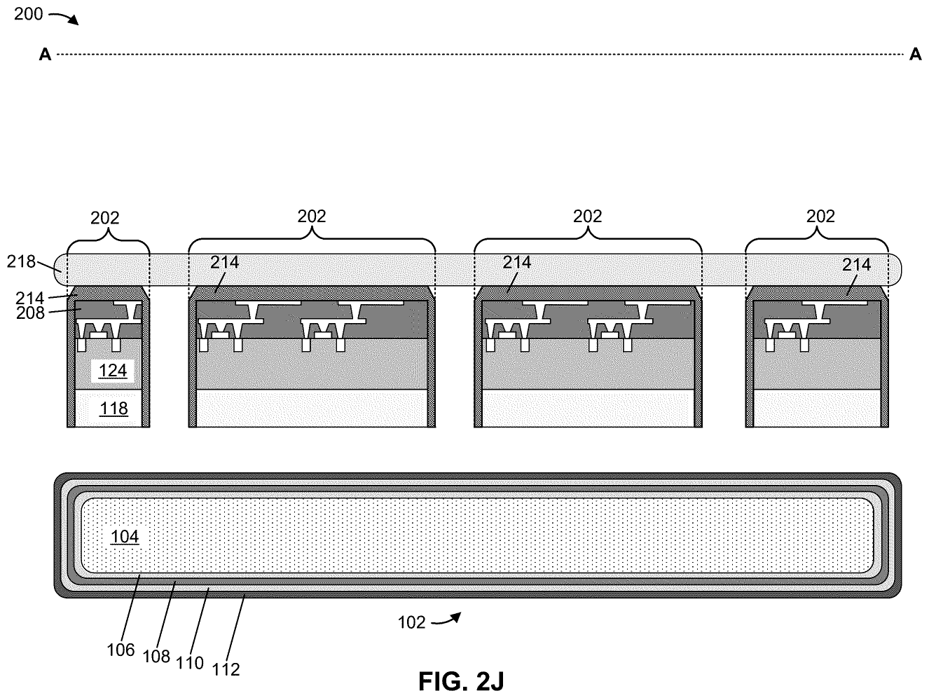

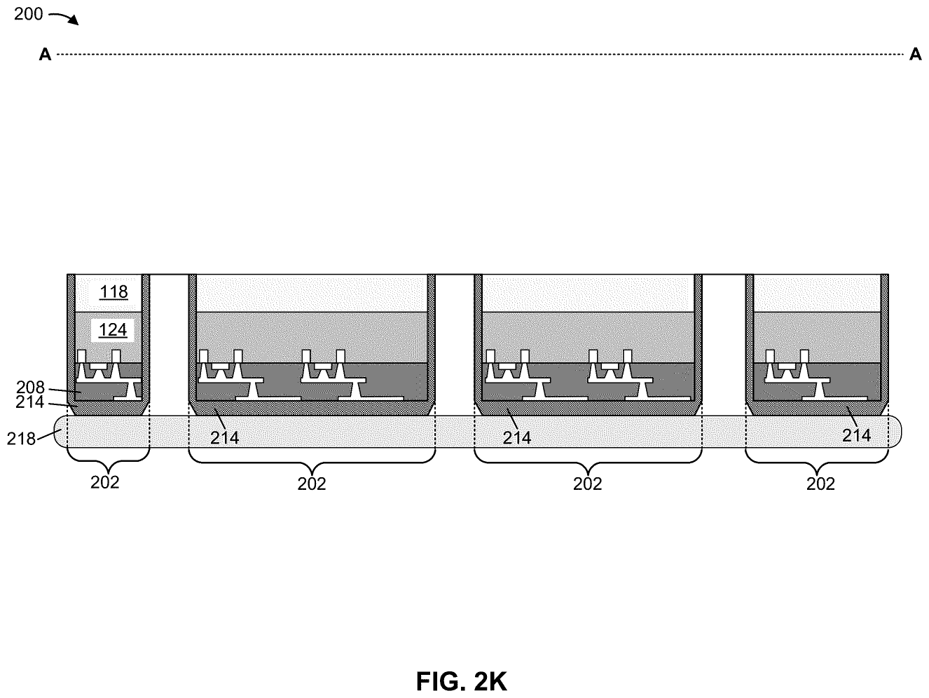

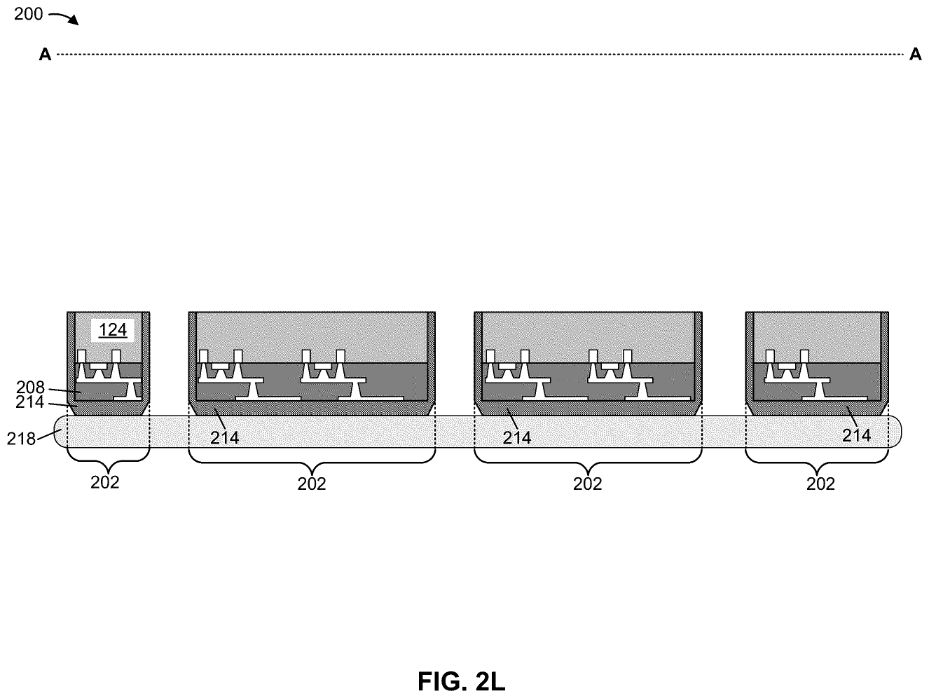

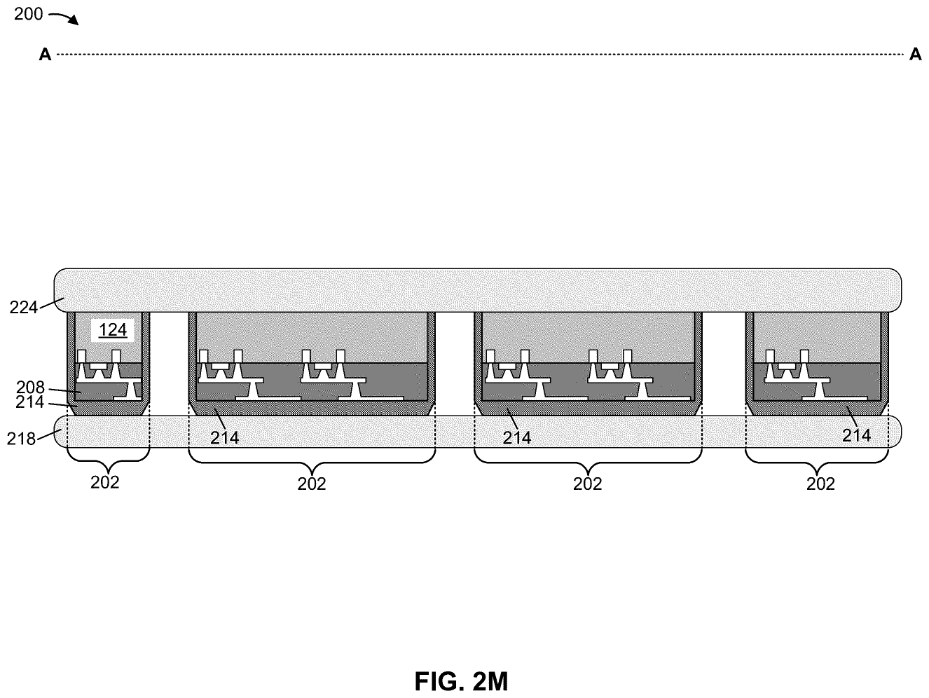

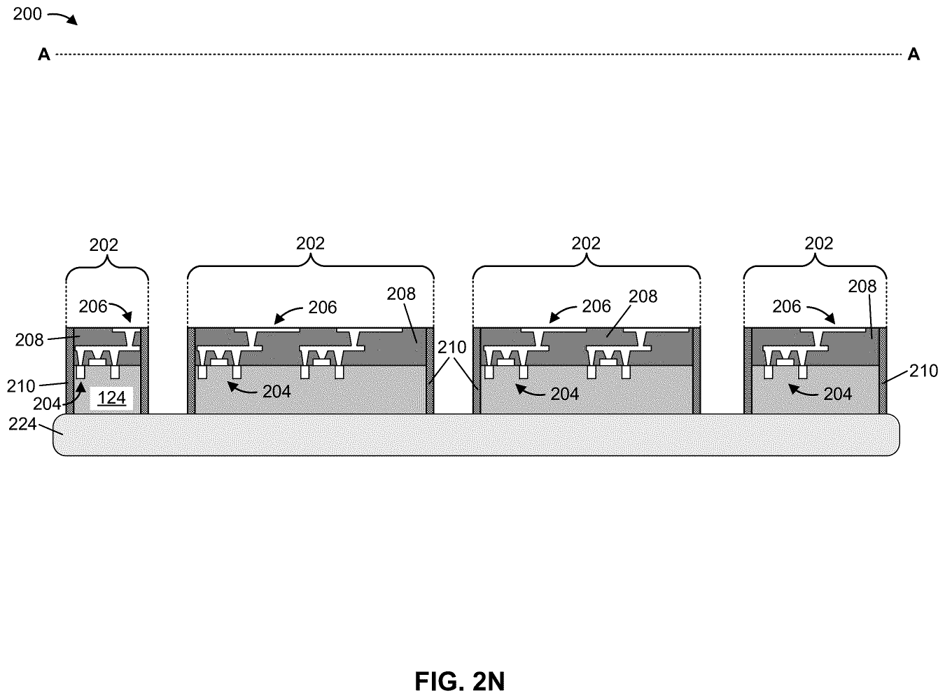

FIGS. 2A-2N are diagrams of an example implementation 200 of forming GaN-based semiconductor devices on a GaN layer 124 that was formed on a core substrate 102 described herein. In particular, the example implementation 200 is an example of a non-destructive process for forming GaN-based semiconductor devices on a GaN layer 124 in a manner that enables the core substrate 102 to be reused multiple times for forming GaN-based semiconductor devices. As described in connection with FIGS. 2A-2N, semiconductor dies that include the GaN-based semiconductor devices are removed from the core substrate 102 by etching through the underlying bonding layer 114 between the semiconductor dies and the core substrate 102 instead of grinding the core substrate 102 down to remove the semiconductor dies. This enables the core substrate 102 to be reused in subsequent GaN-based semiconductor device manufacturing cycles.

As shown in a top view in FIG. 2A, semiconductor dies 202 (e.g., GaN-based semiconductor dies) may be formed on the core substrate 102. As shown in a cross-section view in FIG. 2B along line A-A in FIG. 2A, the semiconductor dies 202 may be formed on the GaN layer 124 that was formed on the core substrate 102. Forming the semiconductor dies 202 may include forming GaN-based semiconductor devices 204 in and/or on the GaN layer 124 for the semiconductor dies 202, forming metallization layers 206 in a dielectric region 208 above the GaN-based semiconductor devices 204, and/or other semiconductor processing operations.

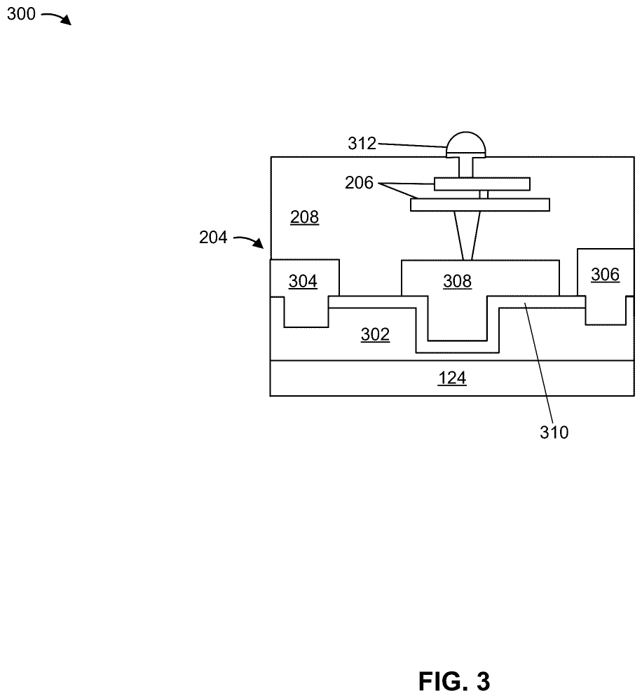

The GaN-based semiconductor devices 204 may include GaN-based HEMTs, GaN-based light emitting diodes (LEDs), GaN-based high-voltage devices (e.g., devices that are configured to operate at voltages of approximately 650 volts or greater), and/or other types of GaN-based semiconductor devices. One or more semiconductor processing tools may be used to form one or more portions of the GaN-based semiconductor devices 204. In some implementations, forming the GaN-based semiconductor devices 204 may include using a deposition tool to deposit one or more layers and/or structures above the GaN layer 124. In some implementations, forming the GaN-based semiconductor devices 204 may include using an exposure tool to expose photoresist layers to form patterns in the photoresist layers, and using an etch tool to etch the GaN layer 124 and/or one or more other layers to form one or more structures of the GaN-based semiconductor devices 204. As another example, a planarization tool may be used to planarize portions of the GaN-based semiconductor devices 204. As another example, a plating tool may be used to deposit metal structures and/or layers of the GaN-based semiconductor devices 204. An example GaN-based semiconductor device 204 is illustrated and described in connection with FIG. 3.

The metallization layers 206 and the dielectric region 208 may correspond to an interconnect layer of a semiconductor die 202. The metallization layers 206 may be included as conductive wiring in the semiconductor die 202 for signal routing and/or power distribution in the semiconductor die 202. The dielectric region 208 may provide electrical isolation for the metallization layers 206.

The dielectric region 208 may include a plurality of dielectric layers (e.g., back end dielectric layers) that are arranged in a direction that is approximately perpendicular to the GaN layer 124. The dielectric layers may include interlayer dielectric (ILD) layers, intermetal dielectric (IMD) layers, and/or etch stop layers (ESLs), among other examples. The dielectric layers of the dielectric region 208 may each include a low dielectric constant (low-k) oxide material such as silicon oxide (SiOₓ), undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, one or more dielectric layers of the dielectric region 208 include an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples. In some implementations, one or more dielectric layers of the dielectric region 208 may include a high dielectric constant (high-k) dielectric material having a dielectric constant greater than that of silicon dioxide (e.g., greater than approximately 3.9). Examples include silicon nitride (SiₓN_{y}), silicon carbide (SIC), silicon oxynitride (SiON), and/or hafnium oxide (HfOₓ), among another example high-k dielectric materials.

One or more of the metallization layers 206 may be electrically coupled and/or physically coupled to one or more of the GaN-based semiconductor devices 204. The metallization layers 206 may be interconnected to provide electrical routing that enables signals and/or power to be provided to and/or from the GaN-based semiconductor devices 204. The metallization layers 206 may include a combination of trenches, metallization layers, conductive traces, contacts, plugs, vias, interconnects, and/or other types of electrically conductive metallization structures, and/or other types of conductive structures. The metallization layers 206 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the dielectric region 208 and the metallization layers 206. The one or more liner layers may include barrier liners, adhesion liners, and/or another type of liners. Examples of materials for the one or more liners include tantalum nitride (TaN) and/or titanium nitride (TiN), among other examples.

In some implementations, the topmost metallization layer 206 may be coupled to connection structures at the top of the semiconductor dies 202. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, bonding pads, and/or other types of connection structures.

One or more deposition tools are used to deposit alternating layers of dielectric layers of the dielectric region 208 using a PVD technique, an ALD technique, a CVD technique, an oxidation technique, and/or another suitable deposition technique. In some implementations, a planarization tool may be used to planarize one or more of the dielectric layers of the dielectric region 208. One or more deposition tools may be used to deposit the metallization layers 206 using a PVD technique, an ALD technique, a CVD technique, an electroplating technique (e.g., an electro-chemical plating technique), and/or another suitable deposition technique. In some implementations, a planarization tool may be used to planarize the metallization layers 206 after the metallization layers 206 are deposited. In some implementations, a seed layer is first deposited, and the metallization layers 206 are formed on the seed layer.

A deposition tool, an exposure tool, a developer tool, an etch tool, a planarization tool, a plating tool, and/or another semiconductor processing tool may be used to perform various operations to form the metallization layers 206 in the dielectric layers of the dielectric region 208. In some implementations, the dielectric region 208 and the metallization layers 206 are built up in a layer-by-layer process flow. For example, one or more first dielectric layers of the dielectric region 208 may be formed (e.g., using one or more deposition tools and/or one or more planarization tools), recesses may be formed in and/or through the one or more first dielectric layers (e.g., by patterning the one or more first dielectric layers using an exposure tool and a developer tool, using an etch tool to etch the one or more first dielectric layers based on a pattern to form the recesses), and a first metallization layer 206 may be formed in the recesses in the one or more first dielectric layers (e.g., using one or more deposition tools and/or one or more planarization tools). Additional dielectric layers of the dielectric region 208 and additional metallization layers 206 may be subsequently formed in a similar manner.

As shown in FIG. 2C, a protection layer 210 is formed above the core substrate 102. In particular, the protection layer 210 is formed across the top surface of the dielectric region 208 such that the protection layer 210 is included on the semiconductor dies 202. The protection layer 210 may include a dielectric material. For example, the protection layer 210 may include a high-k dielectric material such as a high-k dielectric oxide material. As an example, the protection layer 210 may include aluminum oxide (AlₓO_{y} such as Al₂O₃) and/or hafnium oxide (HfOₓ such as HfO₂), among other examples. The material may be selected for the protection layer 210 to have sufficient hardness and etch selectively relative to other materials of the semiconductor dies 202 such that the protection layer 210 can protect the tops of the semiconductor dies 202 from etching.

A deposition tool may be used to deposit the protection layer 210 using a PVD technique, an ALD technique, a CVD technique, an oxidation technique, and/or another suitable deposition technique. The protection layer 210 may be deposited in one or more deposition operations. In some implementations, a planarization tool may be used to perform a planarization operation (e.g., a CMP operation) to planarize the protection layer 210 after the protection layer 210 is deposited. The protection layer 210 may be formed to a first thickness (indicated in FIG. 2C as dimension D1) on the tops of the semiconductor dies 202.

As shown in FIG. 2D, scribe line channels 212 may be formed between the semiconductor dies 202. The scribe line channels 212 may extend from the tops of the semiconductor dies 202 down to the bonding layer 114. In some implementations, the scribe line channels 212 partially extend into the bonding layer 114.

Various techniques and/or processes may be used to form the scribe line channels 212. In some implementations, a pattern in a photoresist layer is used to form the scribe line channels 212. In these implementations, a deposition tool may be used to form the photoresist layer on the protection layer 210 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. One or more etch tools may be used to etch through the protection layer 210, through the dielectric region 208, through the GaN layer 124, and through the semiconductor layer 118 based on the pattern to form the scribe line channels 212. In some implementations, a photoresist removal tool may be used to remove the remaining portions of the photoresist layer (e.g., using a chemical stripper, plasma ashing, and/or another technique).

Additionally and/or alternatively, a hard mask layer may be formed on the protection layer 210 and patterned using a photoresist layer, and the hard mask layer (alone or in combination with the photoresist layer) is used to etch through the protection layer 210, through the dielectric region 208, through the GaN layer 124, and through the semiconductor layer 118 based on the pattern to form the scribe line channels 212.

Various etch techniques may be used to etch through the protection layer 210, through the dielectric region 208, through the GaN layer 124, and through the semiconductor layer 118 to form the scribe line channels 212. Such etch techniques may include dry etch techniques such as plasma-based etching and/or gas-based etching, wet chemical etch techniques, and/or another type of etch technique.

In some implementations, the scribe line channels 212 are formed in a plurality of etch operations. For example, a first etch operation may be performed to etch through the protection layer 210, and one or more second etch operations may be performed to etch through the dielectric region 208, through the GaN layer 124, and/or through the semiconductor layer 118. The first etch operation may include the use of a first etchant, and the one or more second etch operations may include the use of a second etchant that is different from the first etchant. As another example, a first etch operation may be performed to etch through the protection layer 210 (e.g., using a first etchant), a second etch operation may performed after the first etch operation to etch through the dielectric region 208 (e.g., using a second etchant), a third etch operation may performed after the second etch operation to etch through the GaN layer 124 (e.g., using a third etchant), and/or a fourth etch operation may be performed after the third etch operation to etch through the semiconductor layer 118 (e.g., using a fourth etchant).

In some implementations, the sidewalls of the scribe line channels 212 are substantially vertical and parallel. In some implementations, the sidewalls of the scribe line channels 212 have a slight taper from the tops of the scribe line channels 212 to the bottoms of the scribe line channels 212. In other words, the widths of the scribe line channels 212 may decrease from the tops of the scribe line channels 212 to the bottoms of the scribe line channels 212 (e.g., due to the etchant(s) used to form the scribe line channels 212 being in contact with the sidewalls at the tops of the scribe line channels 212 for a longer duration than at the bottoms of the scribe line channels 212).

As shown in a top view of the core substrate 102 in FIG. 2E, the scribe line channels 212 may be included around the perimeters of the semiconductor dies 202. As described in connection with FIGS. 21 and 2J, the scribe line channels 212 are formed around the perimeters of the semiconductor dies 202 to enable the semiconductor dies 202 to be removed from the core substrate 102 without destroying the core substrate 102. Thus, the scribe line channels 212 enable a non-destructive die singulation process to be performed to singulate the semiconductor dies 202 in a manner that enables the core substrate 102 to be reused.

As shown in FIG. 2F, additional portions of the protection layer 210 are formed on the tops of the semiconductor dies 202, on the sidewalls of the semiconductor dies 202 (correspond to the sidewalls of the scribe line channels 212), and on the top surface of the bonding layer 114 in the scribe line channels 212 (corresponding to the bottom surfaces of the scribe line channels 212). Forming the scribe line channels 212 results in cutting the protection layer 210 into a plurality of discontinuous segments that are included on the tops of the semiconductor dies 202. Thus, the additional portions of the protection layer 210 may be formed to merge or rejoin the discontinuous segments such that the protection layer 210 is again a continuous layer of material across the core substrate 102.

A deposition tool may be used to deposit the additional portions of the protection layer 210 using a PVD technique, an ALD technique, a CVD technique, an oxidation technique, and/or another suitable deposition technique. In some implementations, the additional portions of the protection layer 210 may be conformally deposited such that the protection layer 210 conforms to the profile of the scribe line channels 212. Because additional material of the protection layer 210 is formed on the tops of the semiconductor dies 202, the thickness of the protection layer 210 on the tops of the semiconductor dies 202 (indicated in FIG. 2F as dimension D2) may be greater than the thickness of the protection layer 210 on the sidewalls of the of the semiconductor dies 202 (indicated in FIG. 2F as dimension D3).

As shown in FIG. 2G, another etch operation is performed to etch through the protection layer 210 at the bottoms of the scribe line channels 212. Etching through the protection layer 210 at the bottoms of the scribe line channels 212 exposes the bonding layer 114 through the scribe line channels 212. The remaining portions of the protection layer 210 on the sidewalls and on the top surfaces of a semiconductor die 202 correspond to protection spacers 214 on the sidewalls and on the top surfaces of the semiconductor die 202. The protection spacers 214 are formed on the sidewalls and on the top surfaces of the semiconductor dies 202 to protect the semiconductor dies 202 from being etched when a non-destructive die singulation process is performed to singulate the semiconductor dies 202 from the core substrate 102 in a manner that enables the core substrate 102 to be reused.

In some implementations, a highly directional (or anisotropic) etch may be performed to remove the protection layer 210 at the bottoms of the scribe line channels 212 without removing (or with minimal removal of) material from the protection layer 210 on the sidewalls and top surfaces of the semiconductor dies 202. For example, a plasma-based etch operation may be performed, in which a chamber pressure, a temperature, a plasma bias voltage, and/or another parameter is selected to control the directionality of the etch so that a vertical etch is achieved. In some implementations, some material is removed from the protection layer 210 at the edges 216 of the semiconductor dies 202, resulting in the protection spacers 214 at the edges 216 of the semiconductor dies 202 being beveled or rounded.

As shown in FIG. 2H, the tops of the semiconductor dies 202 may be secured to a carrier 218. The carrier 218 may include a benzocyclobutene (BCB) film and/or another type of carrier structure. The semiconductor dies 202 may be secured to a carrier 218 such that the carrier 218 can support the semiconductor dies 202 during and after a non-destructive die singulation process to singulate the semiconductor dies 202 from the core substrate 102. The carrier 218 still provides lateral access to the scribe line channels 212 around the perimeter of the core substrate 102.

As shown in FIGS. 21 and 2J, a non-destructive die singulation process may be performed to singulate the semiconductor dies 202 from the core substrate 102 in a manner that enables the core substrate 102 to be reused. The non-destructive die singulation process may include performing an etch operation to etch the bonding layer 114 to remove the bonding layer 114 between the semiconductor dies 202 and the core substrate 102 to release the semiconductor dies 202 from the core substrate 102. The etch operation may include a wet etch operation in which a wet etchant is provided into the scribe line channels 212 and around the perimeter of the core substrate 102. The wet etchant reacts with the material of the bonding layer 114 to remove the material of the bonding layer through the scribe line channels 212.

As shown in FIG. 2I, recesses 220 are formed in the bonding layer 114 through the scribe line channels 212 as the wet etchant removes material from the bonding layer 114. The wet etchant continues to laterally etch the bonding layer 114 through the recesses 220, resulting in formation of lateral extensions 222 of the recesses 220 under the semiconductor dies 202.

As shown in FIG. 2J, the lateral extensions 222 of the recesses 220 under the semiconductor dies 202 eventually merge as etching of the bonding layer 114 continues, resulting in the bonding layer 114 being fully removed such that the semiconductor dies 202 are released from the core substrate 102.

The wet etchant that is used to etch the bonding layer 114 may partially or fully remove the layers 106-112 from the core substrate 102. However, the AlN core 104 of the core substrate 102 remains intact such that the AlN core 104 can be subsequently used for forming another plurality of semiconductor dies 202 on the core substrate 102 using processes and techniques described in connection with FIGS. 1A-IF and/or 2A-2N, among other examples. Moreover, the wet etchant that is used to etch the bonding layer 114 has a higher etch rate for the material of the bonding layer 114 than the etch rate of the wet etchant for the material of the protection spacers 214 on the semiconductor dies 202. The lower etch rate for the material of the protection spacers 214 on the semiconductor dies 202 enables the protection spacers 214 to protect the semiconductor dies 202 from being etched by the wet etchant without the wet etchant fully etching through the protection spacers 214. In some implementations, the material of the bonding layer 114 is a low-k dielectric material such as silicon oxide (SiOₓ such as SiO₂), the material of the protection spacers 214 is a high-k dielectric material such as aluminum oxide (AlₓO_{y} such as Al₂O₃), and the wet etchant is a hydrofluoric acid (HF) vapor. However, other combinations of materials and wet etchants are within the scope of the present disclosure.

As shown in FIGS. 2K and 2L, the semiconductor dies 202 may be flipped and backside processing may be performed. The backside processing may include planarizing or grinding (e.g., using a planarization tool) the backside of the semiconductor dies 202 to remove the semiconductor layer 118 from the semiconductor dies 202. As indicated above, the GaN-based semiconductor devices 204 formed on the semiconductor dies 202 may include high-voltage devices. Thus, the GaN-based semiconductor devices 204 may generate a high amount of heat during operation of the semiconductor dies 202. Removal of the semiconductor layer 118 may enable more direct heat extraction from the semiconductor dies 202 to be achieved, which may enable lower operating temperatures and increased performance to be achieved for the GaN-based semiconductor devices 204. However, in other implementations, the removal of the semiconductor layer 118 may be omitted, which may reduce the cost and complexity of forming the semiconductor dies 202. In these implementations, the semiconductor layer 118 may be used as a buffer for pick and place of the semiconductor dies 202. For example, a pick and place tool may pick up a semiconductor die 202 (e.g., using electrostatic force, vacuum force) by removably attaching to the semiconductor layer 118 of the semiconductor die 202.

As shown in FIG. 2M, the backside of the semiconductor dies 202 may be secured to another carrier 224. As shown in FIG. 2N, the semiconductor dies 202 may be flipped again, and another planarization operation (e.g., using a planarization tool) may be performed to remove the protection spacers 214 from the tops of the semiconductor dies 202. This enables the topmost metallization layers 206 of the semiconductor dies 202 to be exposed, which enables connection structures to be formed on the semiconductor dies 202 and/or enables the semiconductor dies 202 to be bonded to packaging or to another device or structure. A pick and place tool may be used to remove the semiconductor dies 202 from the carrier 224, and the semiconductor dies 202 may be packaged, may be bonded to other semiconductor dies, and/or may be mounted to a substrate such as a printed circuit board (PCB) or socket, among other examples.

In some implementations, the portions of the protection spacers 214 on the sidewalls of a semiconductor die 202 remain on the sidewalls of the semiconductor die 202 in the final packaged device in which the semiconductor die 202 is included. In some implementations, the portions of the protection spacers 214 on the sidewalls of a semiconductor die 202 are also removed from the sidewalls of the semiconductor die 202 such that the protection spacers 214 are fully removed from the semiconductor die 202. The protection spacers 214 on the sidewalls of a semiconductor die 202 may be removed by etching, ashing, and/or another process.

As indicated above, FIGS. 2A-2N are provided as an example. Other examples may differ from what is described with regard to FIGS. 2A-2N.

FIG. 3 is a diagram of an example implementation 300 of a GaN-based semiconductor device 204 described herein. The GaN-based semiconductor device 204 may include an example of a GaN-based HEMT. As shown in FIG. 3, the GaN-based semiconductor device 204 may be formed in and/or on a GaN layer 124 that was grown on a core substrate 102. The GaN layer 124 may function as a carrier electron layer for the GaN-based semiconductor device 204. The GaN-based semiconductor device 204 may include a channel layer 302 that may include aluminum gallium nitride (AlGaN) and/or another suitable channel layer material.

The GaN-based semiconductor device 204 may further include a plurality of source/drain electrodes 304 and 306 located adjacent to opposing sides of a gate structure. Source/drain electrode(s) may refer to a source or a drain, individually or collectively, depending upon the context. The source/drain electrodes 304 and 306, and/or the gate electrode 308, may extend into the channel layer 302. Alternatively, one or more of the source/drain electrodes 304 and 306, and/or the gate electrode 308, may be included on top of the channel layer 302. The source/drain electrodes 304 and 306, and the gate electrode 308, may each include polysilicon, gold (Au), copper (Cu), silver (Ag), nickel (Ni), tin (Sn), cobalt (Co) and/or another suitable material. In some implementations, a dielectric layer 310 may be included between the gate electrode 308 and the channel layer 302. The dielectric layer 310 may include a high-k dielectric material such as silicon nitride (SiₓN_{y}) and/or hafnium oxide (HfOₓ), a low-k dielectric material, and/or another suitable dielectric material.

As further shown in FIG. 3, the dielectric region 208 and the metallization layers 206 may be included above the GaN-based semiconductor device 204. The metallization layers 206 may electrically connect the GaN-based semiconductor device 204 to one or more connection structures 312. The connection structures 312 may be formed over a top surface of the dielectric region 208 including the metallization layers 206. The connection structures 312 may be electrically connected and/or physically connected with the metallization layers 206. The connection structures 312 may be included in recesses in the top surface of the dielectric region 208. The connection structures 312 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more metal alloys, one or more conductive ceramics, and/or another type of conductive materials.

As indicated above, FIG. 3 is provided as an example. Other examples may differ from what is described with regard to FIG. 3.

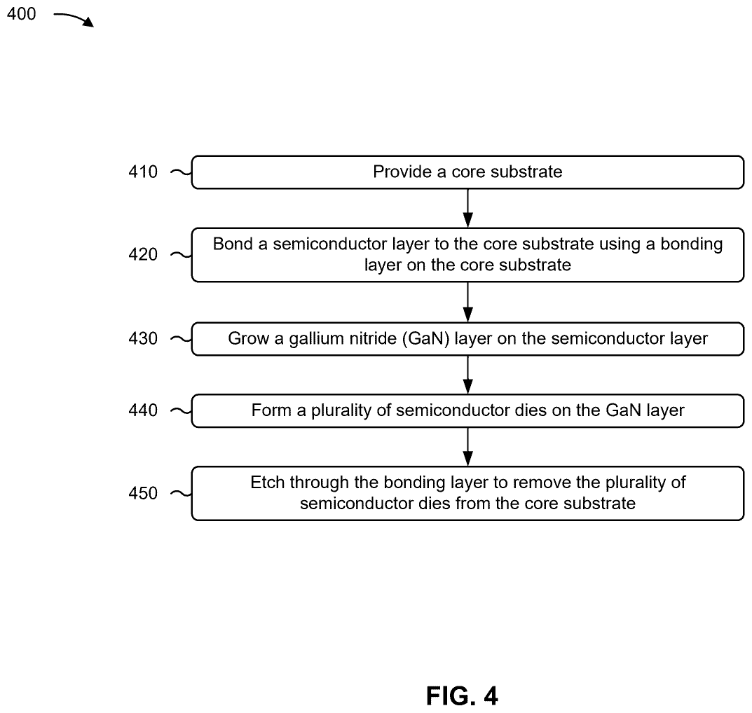

FIG. 4 is a flowchart of an example process 400 associated with forming a GaN-based semiconductor device described herein. In some implementations, one or more process blocks of FIG. 4 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 4, process 400 may include providing a core substrate (block 410). For example, one or more semiconductor processing tools may be used to provide a core substrate 102, as described herein.

As further shown in FIG. 4, process 400 may include bonding a semiconductor layer to the core substrate using a bonding layer on the core substrate (block 420). For example, one or more semiconductor processing tools may be used to bond a semiconductor layer 118 to the core substrate 102 using a bonding layer 114 on the core substrate 102, as described herein.

As further shown in FIG. 4, process 400 may include growing a GaN layer on the semiconductor layer (block 430). For example, one or more semiconductor processing tools may be used to grow a GaN layer 124 on the semiconductor layer 118, as described herein.

As further shown in FIG. 4, process 400 may include forming a plurality of semiconductor dies on the GaN layer (block 440). For example, one or more semiconductor processing tools may be used to form a plurality of semiconductor dies 202 (e.g., GaN-based semiconductor dies) on the GaN layer 124, as described herein.

As further shown in FIG. 4, process 400 may include etching through the bonding layer to remove the plurality of semiconductor dies from the core substrate (block 450). For example, one or more semiconductor processing tools may be used to etch through the bonding layer 114 to remove the plurality of semiconductor dies 202 from the core substrate 102, as described herein.

Process 400 may include additional implementations, such as any single implementation or any combination of implementations described below and/or in connection with one or more other processes described elsewhere herein.

In a first implementation, process 400 includes forming scribe line channels 212 laterally surrounding the plurality of semiconductor dies 202, and etching through the bonding layer 114 includes etching the bonding layer 114 through the scribe line channels 212.

In a second implementation, alone or in combination with the first implementation, etching the bonding layer 114 through the scribe line channels 212 includes providing an etchant into the scribe line channels 212, and laterally etching the bonding layer 114 under the plurality of semiconductor dies 202 using the etchant.

In a third implementation, alone or in combination with one or more of the first and second implementations, the etchant includes a hydrofluoric acid (HF) vapor.

In a fourth implementation, alone or in combination with one or more of the first through third implementations, process 400 includes forming a protection layer 210 on top surfaces and on sidewalls of the plurality of semiconductor dies 202 prior to etching through the bonding layer 114.

In a fifth implementation, alone or in combination with one or more of the first through fourth implementations, etching through the bonding layer 114 includes etching through the bonding layer 114 while the protection layer 210 protects the plurality of semiconductor dies 202 from being etched.

In a sixth implementation, alone or in combination with one or more of the first through fifth implementations, process 400 includes removing the protection layer 210 layer from the top surfaces of the plurality of semiconductor dies 202 after etching through the bonding layer 114.

In a seventh implementation, alone or in combination with one or more of the first through sixth implementations, a thickness (e.g., a dimension D2) of the protection layer 210 on the top surfaces of the plurality of semiconductor dies 202 is greater than a thickness (e.g., a dimension D3) of the protection layer 210 on the sidewalls of the plurality of semiconductor dies 202 prior to etching through the bonding layer 114.

In an eighth implementation, alone or in combination with one or more of the first through seventh implementations, forming the protection layer 210 includes forming a first portion of the protection layer 210 on the top surfaces of the plurality of semiconductor dies 202 prior to forming scribe line channels 212 between the plurality of semiconductor dies 202, and forming second portions of the protection layer 210 on the sidewalls of the plurality of semiconductor dies 202 after forming the scribe line channels 212 between the plurality of semiconductor dies 202.

Although FIG. 4 shows example blocks of process 400, in some implementations, process 400 includes additional blocks, fewer blocks, different blocks, or differently arranged blocks than those depicted in FIG. 4. Additionally, or alternatively, two or more of the blocks of process 400 may be performed in parallel.

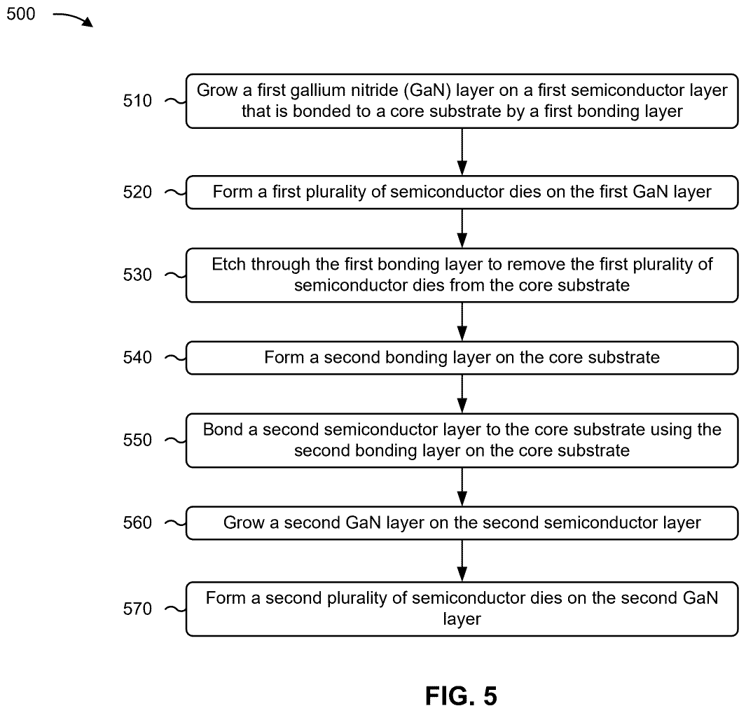

FIG. 5 is a flowchart of an example process 500 associated with forming a GaN-based semiconductor device described herein. In some implementations, one or more process blocks of FIG. 5 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 5, process 500 may include growing a first GaN layer on a first semiconductor layer that is bonded to a core substrate by a first bonding layer (block 510). For example, one or more semiconductor processing tools may be used to grow a first GaN layer 124 on a first semiconductor layer 118 that is bonded to a core substrate 102 by a first bonding layer 114, as described herein.

As further shown in FIG. 5, process 500 may include forming a first plurality of semiconductor dies on the first GaN layer (block 520). For example, one or more semiconductor processing tools may be used to form a first plurality of semiconductor dies 202 (e.g., a first plurality of GaN-based semiconductor dies) on the first GaN layer 124, as described herein.

As further shown in FIG. 5, process 500 may include etching through the first bonding layer to remove the first plurality of semiconductor dies from the core substrate (block 530). For example, one or more semiconductor processing tools may be used to etch through the first bonding layer 114 to remove the first plurality of semiconductor dies 202 from the core substrate 102, as described herein.

As further shown in FIG. 5, process 500 may include forming a second bonding layer on the core substrate (block 540). For example, one or more semiconductor processing tools may be used to form a second bonding layer 114 on the core substrate 102, as described herein.

As further shown in FIG. 5, process 500 may include bonding a second semiconductor layer to the core substrate using the second bonding layer on the core substrate (block 550). For example, one or more semiconductor processing tools may be used to bond a second semiconductor layer 118 to the core substrate 102 using the second bonding layer 114 on the core substrate 102, as described herein.

As further shown in FIG. 5, process 500 may include growing a second GaN layer on the second semiconductor layer (block 560). For example, one or more semiconductor processing tools may be used to grow a second GaN layer 124 on the second semiconductor layer 118, as described herein.

As further shown in FIG. 5, process 500 may include forming a second plurality of semiconductor dies on the second GaN layer (block 570). For example, one or more semiconductor processing tools may be used to form a second plurality of semiconductor dies 202 (e.g., a second plurality of GaN-based semiconductor dies) on the second GaN layer 124, as described herein.

Process 500 may include additional implementations, such as any single implementation or any combination of implementations described below and/or in connection with one or more other processes described elsewhere herein.

In a first implementation, process 500 includes forming scribe line channels 212 laterally surrounding the first plurality of semiconductor dies 202, where etching through the first bonding layer 114 includes etching the first bonding layer 114 through the scribe line channels 212.

In a second implementation, alone or in combination with the first implementation, process 500 includes forming a high-k dielectric protection layer (e.g., a protection layer 210) on top surfaces of the first plurality of semiconductor dies 202 prior to etching through the bonding layer 114, and etching through the high-k dielectric protection layer, the first GaN layer 124, and the first semiconductor layer 118 to form the scribe line channels 212.

In a third implementation, alone or in combination with one or more of the first and second implementations, process 500 includes forming a first portion of a high-k dielectric protection layer on top surfaces of the first plurality of semiconductor dies 202, etching through the first portion of the high-k dielectric protection layer to form scribe line channels 212 laterally surrounding the first plurality of semiconductor dies 202, resulting in formation of a plurality of discontinuous segments from the first portion of the high-k dielectric protection layer, and forming second portions of the high-k dielectric protection layer on sidewalls of the plurality of semiconductor dies 202, where the second portions of the high-k dielectric protection layer merge with the plurality of discontinuous segments of the first portion of the high-k dielectric protection layer.

In a fourth implementation, alone or in combination with one or more of the first through third implementations, process 500 includes forming third portions of the high-k dielectric protection layer at bottoms of the scribe line channels 212 such that the plurality of discontinuous segments, the second portions, and the third portions merge to form a continuous high-k dielectric protection layer, and etching through the third portions of the high-k dielectric protection layer at the bottoms of the scribe line channels 212, where remaining portions of the high-k dielectric protection layer on the sidewalls and top surfaces of the semiconductor dies 202 correspond to protection spacers 214 on the sidewalls and top surfaces of the semiconductor dies 202.

In a fifth implementation, alone or in combination with one or more of the first through fourth implementations, etching the first bonding layer 114 through the scribe line channels 212 includes providing an etchant into the scribe line channels 212, where the etchant has a greater etch rate for the first bonding layer 114 than an etch rate of the etchant for the high-k dielectric protection layer, and laterally etching the first bonding layer 114 under the first plurality of semiconductor dies 202 using the etchant.

In a sixth implementation, alone or in combination with one or more of the first through fifth implementations, the first bonding layer 114 includes a low-k dielectric oxide material, and the high-k dielectric protection layer is a high-k dielectric oxide material.

In a seventh implementation, alone or in combination with one or more of the first through sixth implementations, the etchant includes a hydrofluoric (HF) acid vapor.

In an eighth implementation, alone or in combination with one or more of the first through seventh implementations, forming the second bonding layer includes forming the second bonding layer around the core substrate and removing a first portion of the second bonding layer from a first surface of the core substrate such that a second portion of the second bonding layer remains on a second surface of the core substrate vertically opposite the first surface, and bonding the second semiconductor layer to the core substrate using the second bonding layer includes bonding the second semiconductor layer to the core substrate using the second portion of the second bonding layer on the second surface of the core substrate.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

In this way, scribe line channels are formed between semiconductor dies that are formed on a GaN layer using an AlN-based core substrate. The scribe line channels are formed to expose a release layer under the GaN layer, which enables the release layer to be etched through the scribe line channels to remove the semiconductor dies from the AlN-based core substrate with minimal to no damage to the AlN-based core substrate. In this way, the scribe line channels enable the AlN-based core substrate to be reused for subsequent GaN layer growth, and increase the number of times that the AlN-based core substrate can be reused to form GaN-based semiconductor devices. This reduces the cost and complexity of manufacturing GaN-based HEMTs and other GaN-based semiconductor devices.

As described in greater detail above, some implementations described herein provide a method. The method includes providing a core substrate. The method includes bonding a semiconductor layer to the core substrate using a bonding layer on the core substrate. The method includes growing a GaN layer on the semiconductor layer. The method includes forming a plurality of semiconductor dies on the GaN layer. The method includes etching through the bonding layer to remove the plurality of semiconductor dies from the core substrate.

As described in greater detail above, some implementations described herein provide a method. The method includes growing a first GaN layer on a first semiconductor layer that is bonded to a core substrate by a first bonding layer. The method includes forming a first plurality of semiconductor dies on the first GaN substrate. The method includes etching through the first bonding layer to remove the first plurality of semiconductor dies from the core substrate. The method includes forming a second bonding layer on the core substrate. The method includes bonding a second semiconductor layer to the core substrate using the second bonding layer on the core substrate. The method includes growing a second GaN substrate on a second semiconductor layer. The method includes forming a second plurality of semiconductor dies on the first GaN substrate.

As described in greater detail above, some implementations described herein provide a semiconductor device. The semiconductor device includes a GaN layer. The semiconductor device includes one or more HEMT structures in the GaN layer. The semiconductor device includes one or more interconnect structures in a dielectric layer above the GaN layer. The semiconductor device includes protection spacers on sidewalls of the semiconductor device.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a core substrate;
bonding a semiconductor layer to the core substrate using a bonding layer on the core substrate;
growing a gallium nitride (GaN) layer on the semiconductor layer;
forming a plurality of semiconductor dies on the GaN layer; and
etching through the bonding layer to remove the plurality of semiconductor dies from the core substrate.

2. The method of claim 1, further comprising:
forming scribe line channels laterally surrounding the plurality of semiconductor dies,
wherein etching through the bonding layer comprises:
etching the bonding layer through the scribe line channels.

3. The method of claim 2, wherein etching the bonding layer through the scribe line channels comprises:
providing an etchant into the scribe line channels; and
laterally etching the bonding layer under the plurality of semiconductor dies using the etchant.

4. The method of claim 3, wherein the etchant comprises a hydrofluoric acid vapor.

5. The method of claim 1, further comprising:
forming a protection spacer on top surfaces and on sidewalls of the plurality of semiconductor dies prior to etching through the bonding layer.

6. The method of claim 5, wherein etching through the bonding layer comprises:
etching through the bonding layer while the protection spacer protects the plurality of semiconductor dies from being etched.

7. The method of claim 6, further comprising:
removing the protection spacer from the top surfaces of the plurality of semiconductor dies after etching through the bonding layer.

8. The method of claim 5, wherein a thickness of the protection spacer on the top surfaces of the plurality of semiconductor dies is greater than a thickness of the protection spacer on the sidewalls of the plurality of semiconductor dies prior to etching through the bonding layer.

9. The method of claim 5, wherein forming the protection spacer comprises:
forming a first portion of the protection spacer on the top surfaces of the plurality of semiconductor dies prior to forming scribe line channels between the plurality of semiconductor dies; and
forming second portions of the protection spacer on the sidewalls of the plurality of semiconductor dies after forming the scribe line channels between the plurality of semiconductor dies.

10. A method, comprising:
growing a first gallium nitride (GaN) layer on a first semiconductor layer that is bonded to a core substrate by a first bonding layer;
forming a first plurality of semiconductor dies on the first GaN layer;
etching through the first bonding layer to remove the first plurality of semiconductor dies from the core substrate;
forming a second bonding layer on the core substrate;
bonding a second semiconductor layer to the core substrate using the second bonding layer on the core substrate;
growing a second GaN layer on a second semiconductor layer; and
forming a second plurality of semiconductor dies on the second GaN layer.

11. The method of claim 10, further comprising:
forming scribe line channels laterally surrounding the first plurality of semiconductor dies,
wherein etching through the first bonding layer comprises:
etching the first bonding layer through the scribe line channels.

12. The method of claim 11, further comprising:
forming a high dielectric constant (high-k) dielectric protection layer on top surfaces of the first plurality of semiconductor dies prior to etching through the bonding layer; and
etching through the high-k dielectric protection layer, the first GaN layer, and the first semiconductor layer to form the scribe line channels.

13. The method of claim 10, further comprising:
forming a first portion of a high dielectric constant (high-k) dielectric protection layer on top surfaces of the first plurality of semiconductor dies;
etching through the first portion of the high-k dielectric protection layer to form scribe line channels laterally surrounding the first plurality of semiconductor dies, resulting in formation of a plurality of discontinuous segments from the first portion of the high-k dielectric protection layer; and
forming second portions of the high-k dielectric protection layer on sidewalls of the first plurality of semiconductor dies,
wherein the second portions of the high-k dielectric protection layer merge with the plurality of discontinuous segments of the first portion of the high-k dielectric protection layer.

14. The method of claim 13, further comprising:
forming third portions of the high-k dielectric protection layer at bottoms of the scribe line channels such that the plurality of discontinuous segments, the second portions, and the third portions merge to form a continuous high-k dielectric protection layer; and
etching through the third portions of the high-k dielectric protection layer at the bottoms of the scribe line channels,
wherein remaining portions of the high-k dielectric protection layer on the sidewalls of the first plurality of semiconductor dies and on the top surfaces of the first plurality of semiconductor dies.

15. The method of claim 13, wherein etching the first bonding layer through the scribe line channels comprises:
providing an etchant into the scribe line channels,
wherein the etchant has a greater etch rate for the first bonding layer than an etch rate of the etchant for the high-k dielectric protection layer; and
laterally etching the first bonding layer under the first plurality of semiconductor dies using the etchant.

16. The method of claim 15, wherein the first bonding layer comprises a low dielectric constant (low-k) dielectric oxide material; and
wherein the high-k dielectric protection layer comprises a high-k dielectric oxide material.

17. The method of claim 10, wherein forming the second bonding layer comprises:
forming the second bonding layer around the core substrate; and
removing a first portion of the second bonding layer from a first surface of the core substrate such that a second portion of the second bonding layer remains on a second surface of the core substrate vertically opposite the first surface; and
wherein bonding the second semiconductor layer to the core substrate using the second bonding layer comprises:
bonding the second semiconductor layer to the core substrate using the second portion of the second bonding layer on the second surface of the core substrate.

18. A semiconductor device, comprising:
a gallium nitride (GaN) layer;
one or more high-electron-mobility transistor (HEMT) structures in the GaN layer;
one or more interconnect structures in a dielectric layer above the GaN layer; and
protection spacers on sidewalls of the semiconductor device.

19. The semiconductor device of claim 18, wherein the protection spacers include a high dielectric constant (high-k) dielectric material.

20. The semiconductor device of claim 19, wherein the high-k dielectric material comprises aluminum oxide (AlₓO_{y}).
